(19) United States
(12) Patent Application Publication
(10) Pub. No.: US 2025/0191963 A1
(43) Pub. Date: Jun. 12, 2025

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Toshiki FUJINO, Toyama-shi (JP); Masakazu SHIMADA, Toyama-shi (JP); Hisashi JIZO, Toyama-shi (JP); Akinori ISHII, Toyama-shi (JP); Yukinori ABURATANI, Toyama-shi (JP); Takeshi KASAI, Toyama-shi (JP)

(73) Assignee: KOKUSAI ELECTRIC CORPORATION, Tokyo (JP)

(21) Appl. No.: 19/057,279

(22) Filed: Feb. 19, 2025

Related U.S. Application Data
(63) Continuation of application No. PCT/JP2022/035331, filed on Sep. 22, 2022.

(51) Int. Cl. H01L 21/687; H01L 21/67; H01L 21/673; H01L 21/683

(52) U.S. Cl. CPC H01L 21/68742; H01L 21/67069; H01L 21/673; H01L 21/6835; H01L 2221/68318

(57) ABSTRACT

A boat includes a first support for one substrate, a processing container that accommodates the boat and processes the substrate, a gas supplier that supplies a processing gas into the processing container, second supports provided to be relatively movable in a vertical direction with respect to the boat, a rotator including a rotation shaft that supports the boat, a driver that is capable of lifting the second supports relatively upward to float the substrate from the at least one first support, and a controller that is capable of controlling to form a film on the substrate by performing a step a of supplying a gas from the gas supplier while rotating the boat to process the substrate supported by the boat, and a step b of separating the substrate from the first support while maintaining the substrate in the processing container a predetermined number of times.

### CROSS-REFERENCE TO RELATED APPLICATIONS

This application is a Bypass Continuation Application of PCT International Application No. PCT/JP2022/035331, filed on Sep. 9, 2022, the entire contents of which are incorporated herein by reference.

### BACKGROUND

### Field

The present disclosure relates to a substrate processing apparatus, a method of manufacturing a semiconductor device, and a recording medium.

### Description of the Related Art

Some substrate processing apparatuses serving as semiconductor manufacturing apparatuses that process a semiconductor substrate (substrate) include a substrate processing apparatus in which a boat serving as a substrate support in which a large number of semiconductor substrates are stored is arranged inside a vertical processing furnace to perform film-forming processing.

### SUMMARY

In a case where a thick film is formed on a substrate, sticking between a substrate support and the substrate occurs due to a film formed in the vicinity of a contact between the substrate and the substrate support, and particles might be generated when such substrate is taken out from the substrate support.

The present disclosure provides a technique for preventing sticking of the substrate to the support accompanying film formation.

Other objects and novel features will be apparent from the description of the present specification and the attached drawings.

An outline of representative ones of the present disclosure will be briefly described below.

According to an aspect of the present disclosure, provided is a technique provided with a boat including at least one first support for one substrate, a processing container that accommodates the boat and processes the substrate that is placed, a gas supplier that supplies a processing gas into the processing container, a plurality of second supports provided so as to be relatively movable in a vertical direction with respect to the boat, a rotator including a rotation shaft that rotatably supports the boat, a driver that is capable of lifting the second supports relatively upward to float the substrate from the at least one first support, and a controller that controls to form a film on the substrate by performing a step a of supplying a gas from the gas supplier while rotating the boat to process the substrate supported by the boat, and a step b of separating the substrate from the first support while maintaining the substrate in the processing container a predetermined number of times.

### BRIEF DESCRIPTION OF THE DRAWINGS

FIG. 1 is a schematic configuration diagram of a vertical processing furnace of a substrate processing apparatus suitably used in an aspect of the present disclosure, and is a longitudinal cross-sectional view of a portion of a processing furnace 202.

FIG. 2 is a schematic configuration diagram of the vertical processing furnace of the substrate processing apparatus suitably used in an aspect of the present disclosure, and is a cross-sectional view of the portion of the processing furnace 202 taken along line A-A in FIG. 1.

FIG. 3 is a perspective view of a main boat 217a suitably used in an aspect of the present disclosure.

FIG. 4 is a perspective view of a sub boat 217b suitably used in an aspect of the present disclosure.

FIG. 5 is a cross-sectional perspective view of a furnace opening for illustrating a driver suitably used in an aspect of the present disclosure.

FIG. 6 is a longitudinal cross-sectional view of the vicinity of a bottom plate of a boat suitably used in an aspect of the present disclosure, and is a cross-sectional view for illustrating a sub boat loading table to which the sub boat 217b is fixed.

FIG. 7 is a schematic configuration diagram of a controller 121 of the substrate processing apparatus suitably used in an aspect of the present disclosure, and is a block diagram illustrating a control system of the controller 121.

FIG. 8 is a diagram illustrating a process flow in an aspect of the present disclosure.

FIG. 9 is a diagram for illustrating a driver according to Modified Example 1.

FIG. 10 is a diagram for illustrating a driver according to Modified Example 2.

FIG. 11 is a diagram for illustrating a driver according to Modified Example 3.

### DETAILED DESCRIPTION

An aspect of the present disclosure will be described below with reference to the drawings. Note that the drawings used in the following description are all schematic, and a dimensional relationship between respective elements, a ratio between the respective elements and the like illustrated in the drawings do not necessarily coincide with actual ones. The dimensional relationships between the respective elements, the ratios between the respective elements and the like do not necessarily coincide with each other between a plurality of drawings.

### (1) Configuration of Substrate Processing Apparatus

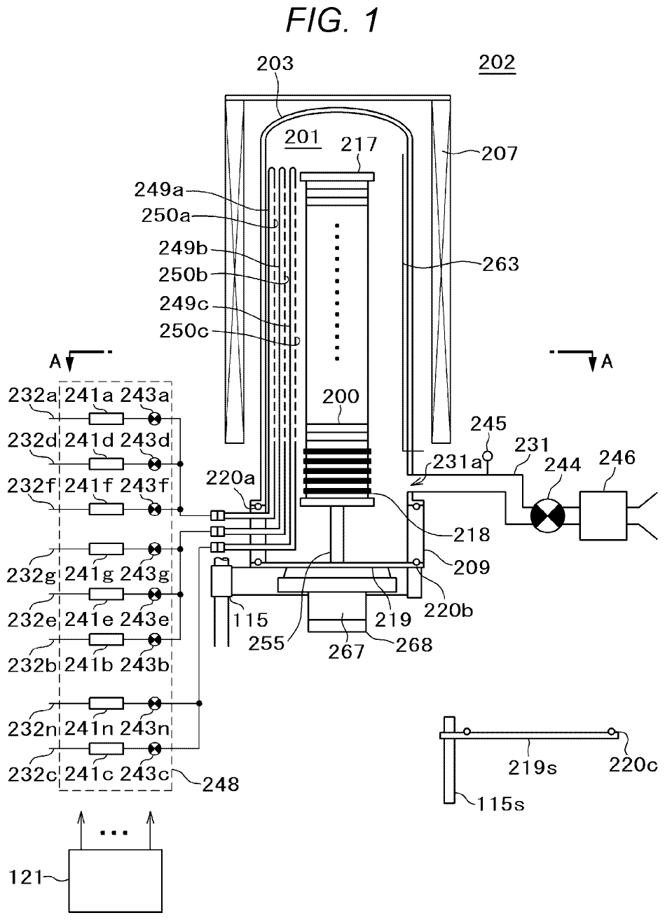

As illustrated in FIG. 1, a processing furnace 202 includes a heater 207 serving as a temperature regulator (heater). The heater 207 has a cylindrical shape and is supported by a holding plate to be vertically installed. The heater 207 also functions as an activator (exciter) that thermally activates (excites) a gas.

Inside the heater 207, a reaction tube 203 is arranged concentrically with the heater 207. The reaction tube 203 is composed of, for example, a heat-resistant material such as quartz (SiO₂) or silicon carbide (Sic), and is formed into a cylindrical shape with an upper end closed and a lower end opened. A manifold 209 is arranged below the reaction tube 203 concentrically with the reaction tube 203. The manifold 209 is composed of a metal material such as stainless steel (SUS), for example, into a cylindrical shape with an upper end and lower end opened. An upper end portion of the manifold 209 engages with a lower end portion of the reaction tube 203 and is configured to support the reaction tube 203. An O-ring 220a serving as a seal is provided between the manifold 209 and the reaction tube 203. The reaction tube 203 is vertically installed similarly to the heater 207. A processing container (reaction container) is mainly composed of the reaction tube 203 and the manifold 209. A process chamber 201 is formed in a cylinder hollow portion of the processing container. The process chamber 201 is configured to be able to accommodate a wafer 200 serving as a substrate. The wafer 200 is processed in the process chamber 201.

In the process chamber 201, nozzles 249a to 249c serving as first to third suppliers, respectively, are provided so as to penetrate a side wall of the manifold 209. The nozzles 249a to 249c are also referred to as first to third nozzles, respectively. The nozzles 249a to 249c are each composed of, for example, a heat-resistant material such as quartz or SiC. Gas supply pipes 232a to 232c are connected to the nozzles 249a to 249c, respectively. The nozzles 249a to 249c are nozzles different from one another, and the nozzles 249a and 249c are provided adjacent to the nozzle 249b.

The gas supply pipes 232a to 232c are provided with mass flow controllers (MFCs) 241a to 241c as flow rate controllers (flow rate controllers), and valves 243a to 243c as opening/closing valves, respectively, in this order from an upstream side of a gas flow. Gas supply pipes 232d and 232f are connected to the gas supply pipe 232a on a downstream side of the valve 243a. Gas supply pipes 232e and 232g are connected to the gas supply pipe 232b on a downstream side of the valve 243b. A gas supply pipe 232h is connected to the gas supply pipe 232c on a downstream side of the valve 243c. The gas supply pipes 232d to 232h are provided with MFCs 241d to 241h and valves 243d to 243h, respectively, in this order from the upstream side of the gas flow. The gas supply pipes 232a to 232h are each composed of, for example, a metal material such as SUS.

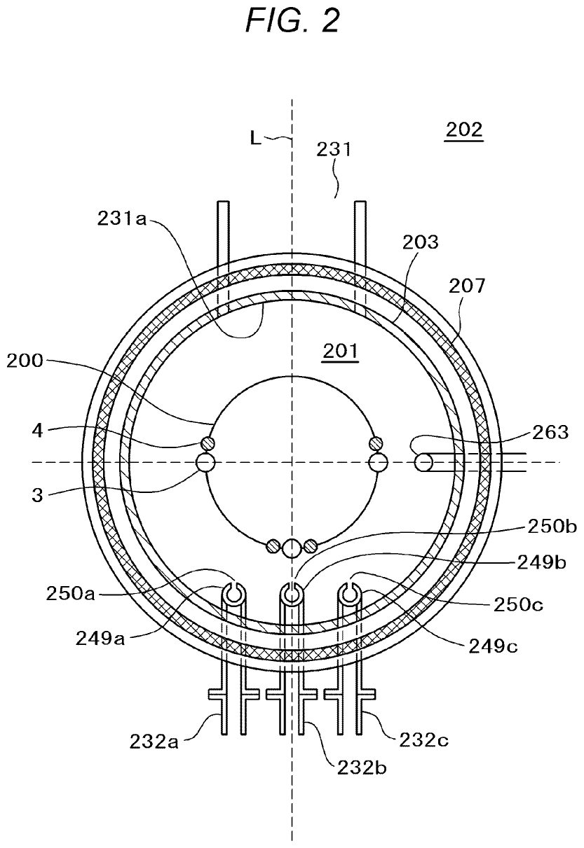

As illustrated in FIG. 2, the nozzles 249a to 249c are provided in an annular space in a plan view between an inner wall of the reaction tube 203 and the wafer 200 so as to extend upward in an arrangement direction of the wafers 200 along the inner wall of the reaction tube 203 from a lower portion toward an upper portion. That is, the nozzles 249a to 249c are provided along a wafer arrangement region, in a region horizontally surrounding the wafer arrangement region, on a lateral side of the wafer arrangement region in which the wafers 200 are arranged. In a plan view, the nozzle 249b is arranged so as to be opposed to an exhaust port 231a, which will be described later, on a straight line with the center of the wafer 200 loaded into the process chamber 201 interposed therebetween. The nozzles 249a and 249c are arranged so as to interpose a straight line L passing through the nozzle 249b and the center of the exhaust port 231a from both sides along the inner wall of the reaction tube 203 (an outer peripheral portion of the wafer 200). The straight line L also passes through the nozzle 249b and the center of the wafer 200. That is, it can also be said that the nozzle 249c is provided on a side opposite to the nozzle 249a across the straight line L. The nozzles 249a and 249c are arranged in line symmetry with the straight line L as a symmetry axis. On side surfaces of the nozzles 249a to 249c, gas supply holes 250a to 250c through which a gas is supplied are provided, respectively. The gas supply holes 250a to 250c are each opened so as to be opposed to (face) the exhaust port 231a in a plan view, and can supply the gas toward the wafer 200. The gas supply holes 250a to 250c are provided from the lower portion toward the upper portion of the reaction tube 203.

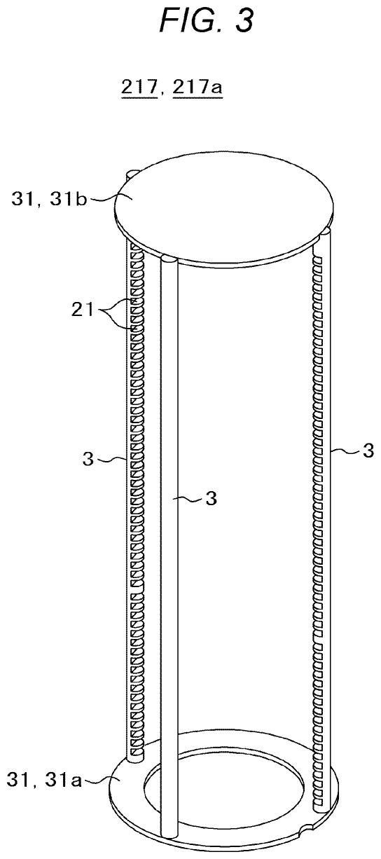

A plurality of fixed struts 3 of a main boat 217a illustrated in FIG. 3 and a plurality of movable struts 4 of a sub boat 217b are drawn on the outer peripheral portion of the wafer 200.

An etching gas is supplied from the gas supply pipe 232a into the process chamber 201 via the MFC 241a, the valve 243a, and the nozzle 249a. As the etching gas, for example, a fluorine (F)— containing gas can be used.

A reduction gas is supplied from the gas supply pipe 232b into the process chamber 201 via the MFC 241b, the valve 243b, and the nozzle 249b. As the reduction gas, for example, hydrogen (H)— containing gas can be used.

A second processing gas serving as a source gas is supplied from the gas supply pipe 232c into the process chamber 201 via the MFC 241c, the valve 243c, and the nozzle 249c. As the second processing gas, for example, a gas containing a group 14 element such as germanium (Ge) can be used.

A first processing gas serving as a source gas is supplied from the gas supply pipe 232d into the process chamber 201 via the MFC 241d, the valve 243d, the gas supply pipe 232a, and the nozzle 249a. As the first source gas, for example, a gas containing a group 14 element such as silicon (Si) can be used.

A second processing gas serving as a dopant gas is supplied from the gas supply pipe 232e into the process chamber 201 via the MFC 241e, the valve 243e, the gas supply pipe 232b, and the nozzle 249b.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c, respectively. The inert gas acts as a purge gas, a carrier gas, a diluent gas and the like.

An etching gas supply system (F and H-containing gas supply system) is mainly composed of the gas supply pipe 232a, the MFC 241a, and the valve 243a. A reduction gas supply system is mainly composed of the gas supply pipe 232b, the MFC 241b, and the valve 243b. A second processing gas supply system (Ge-containing gas supply system) is mainly composed of the gas supply pipe 232c, the MFC 241c, and the valve 243c. A first processing gas supply system (Si-containing gas supply system) is mainly composed of the gas supply pipe 232d, the MFC 241d, and the valve 243d. A second processing gas supply system (dopant gas supply system) is mainly composed of the gas supply pipe 232e, the MFC 241e, and the valve 243e. An inert gas supply system is mainly composed of the gas supply pipes 232f to 232h, the MFCs 241f to 241h, and the valves 243f to 243h.

Any one or all of the various supply systems described above may be formed as an integrated supply system 248 in which the valves 243a to 243h, the MFCs 241a to 241h and the like are integrated. The integrated supply system 248 is connected to each of the gas supply pipes 232a to 232h, and is configured such that a supplying operation of various substances (various gases) into the gas supply pipes 232a to 232h, that is, an opening/closing operation of the valves 243a to 243h, a flow rate regulating operation by the MFCs 241a to 241h and the like are controlled by a controller 121 to be described later. The integrated supply system 248 is configured as an integral or separated integrated unit, and can be attached to or detached from the gas supply pipes 232a to 232h and the like on an integrated unit basis, so that the integrated supply system 248 can be maintained, replaced, or added on an integrated unit basis.

The exhaust port 231a from which an atmosphere inside the process chamber 201 is discharged is provided in a lower portion of a side wall of the reaction tube 203. As illustrated in FIG. 2, the exhaust port 231a is provided at a position opposed to (facing) the nozzles 249a to 249c (gas supply holes 250a to 250c) across the wafer 200 in a plan view. The exhaust port 231a may be provided along the side wall of the reaction tube 203 from the lower portion toward the upper portion, that is, along the wafer arrangement region. An exhaust pipe 231 is connected to the exhaust port 231a. A vacuum pump 246 serving as a vacuum exhauster is connected to the exhaust pipe 231 via a pressure sensor 245 serving as a pressure detector (pressure detector) that detects a pressure in the process chamber 201 and an auto pressure controller (APC) valve 244 serving as a pressure regulator (pressure regulator). The APC valve 244 is configured to be able to vacuum-exhaust the process chamber 201 and stop the vacuum-exhaust by opening and closing a valve in a state in which the vacuum pump 246 is operating, and further regulate the pressure in the process chamber 201 by adjusting a degree of valve opening on the basis of pressure information detected by the pressure sensor 245 in a state in which the vacuum pump 246 is operating. An exhaust system is mainly composed of the exhaust pipe 231, the APC valve 244, and the pressure sensor 245. The vacuum pump 246 may be included in the exhaust system.

A seal cap 219 serving as a lid serving as a furnace opening lid capable of airtightly closing a lower end opening of the manifold 209 is provided below the manifold 209. The seal cap 219 is composed of, for example, a metal material such as SUS into a disk shape. On an upper surface of the seal cap 219, an O-ring 220b serving as a seal that abuts the lower end of the manifold 209 is provided. A rotator 267 serving as a rotator that rotates a boat 217 (main boat 217a and sub boat 217b) to be described later is disposed below the seal cap 219. A rotation shaft 255 of the rotator 267 penetrates the seal cap 219 and is connected to the boat 217. The rotator 267 is configured to rotate the wafer 200 by rotating the boat 217. The rotator 267 and the seal cap 219 are configured to be elevated in a vertical direction by a boat elevator 115 serving as an elevator arm serving as an elevator disposed outside the reaction tube 203. That is, the boat elevator 115 serving as the elevator arm can drive the rotator 267 and a lid (seal cap 219) up and down. The boat elevator 115 is configured as a carrier (carrier) that elevates the seal cap 219, thereby loading and unloading (carrying) the wafer 200 into/from the process chamber 201.

A driver 268 is provided below the seal cap 219. The driver 268 is used to simultaneously lift a plurality of wafers 200 in the boat 217 in the middle of film-forming processing in the process chamber 201.

Below the manifold 209, a shutter 219s serving as a furnace opening lid capable of airtightly closing the lower end opening of the manifold 209 in a state in which the seal cap 219 is lowered and the boat 217 is unloaded from the inside of the process chamber 201 is provided. The shutter 219s is composed of, for example, a metal material such as SUS into a disk shape. An O-ring 220c serving as a seal that abuts the lower end of the manifold 209 is provided on an upper surface of the shutter 219s. An opening/closing operation (an elevating operation, a turning operation and the like) of the shutter 219s is controlled by a shutter opener/closer 115s.

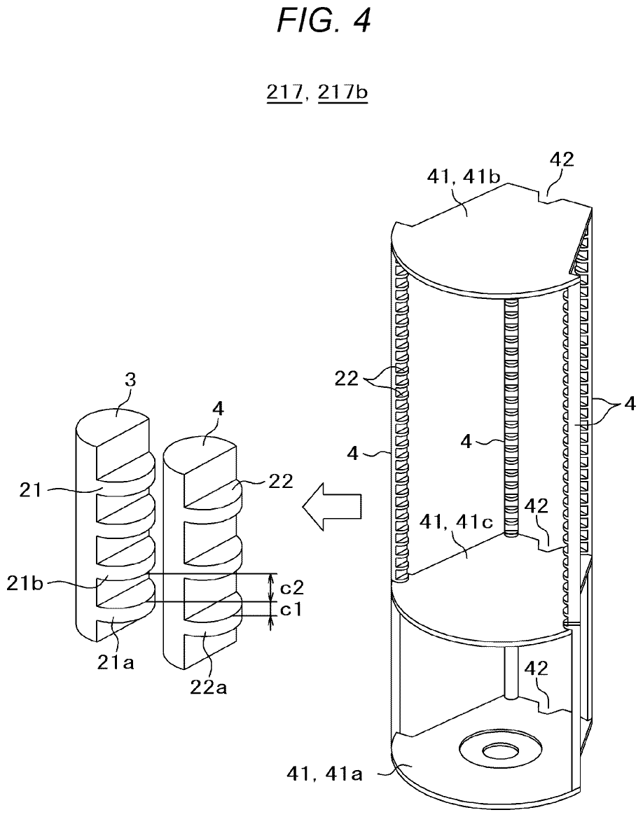

The boat 217 serving as a substrate support includes the main boat 217a illustrated in FIG. 3 and the sub boat 217b illustrated in FIG. 4, and the main boat 217a and the sub boat 217b are combined. Note that the main boat 217a can also be simply referred to as a boat 217a.

The main boat 217a includes a plurality of first supports 21 configured to support a plurality of, for example, 25 to 200 wafers 200 horizontally, in multiple stages so as to be aligned in the vertical direction with the centers aligned with one another, that is, to arrange at intervals. That is, the main boat 217a includes at least one first support 21 for one substrate (wafer). The main boat 217a is composed of, for example, a heat-resistant material such as quartz and SiC. As illustrated in FIG. 1, heat insulating plates 218 each composed of, for example, a heat-resistant material such as quartz or Sic are supported in multiple stages in a lower portion of the boat 217a.

As illustrated in FIG. 3, the main boat 217a includes the plurality of fixed struts 3 (herein, three fixed struts) extending in a direction substantially perpendicular to the wafer 200 and provided with the first supports, respectively, and a first coupler 31 that fixes the plurality of fixed struts 3 to each other, and the first coupler 31 includes a first bottom plate 31a that fixes the vicinity of lower ends of the plurality of fixed struts 3 to each other and a first upper plate 31b that fixes the vicinity of upper ends of the plurality of fixed struts 3 to each other. Each of the plurality of fixed struts 3 is provided with the plurality of first supports 21.

The sub boat 217b includes a plurality of second supports 22 configured to support the plurality of, for example, 25 to 200 wafers 200 horizontally, in multiple stages so as to be aligned in the vertical direction with the centers aligned with one another, that is, to arrange at intervals. The plurality of second supports 22 is provided so as to be relatively movable in the vertical direction with respect to the main boat 217a. The sub boat 217b is composed of, for example, a heat-resistant material such as quartz and SiC.

As illustrated in FIG. 4, the sub boat 217b includes the plurality of movable struts 4 (herein, four movable struts) extending in the direction substantially perpendicular to the wafer 200 and provided with the second supports 22, respectively, and a second coupler 41 that fixes the plurality of movable struts 4 to each other, and the second coupler 41 includes a second bottom plate 41a that fixes the vicinity of lower ends of the plurality of movable struts 4 to each other, a second upper plate 41b that fixes the vicinity of upper ends of the plurality of movable struts 4 to each other, and an intermediate plate 41c that fixes the vicinity of intermediate portions (portions between the upper ends and the lower ends) of the plurality of movable struts 4 to each other. Each of the plurality of movable struts 4 is provided with the plurality of second supports 22. The second upper plate 41b and the second bottom plate 41a of the sub boat 217b can be fitted between the first upper plate 31b and the first bottom plate 31a of the main boat 217a. As illustrated in FIG. 2, the plurality of movable struts 4 is arranged so as to be rotatable together with the main boat 217a on the outer periphery of the substrate 200 supported by the main boat 217a in a manner capable of being separated from and in contact with the driver 268.

The second bottom plate 41a is a plate having a shape that can be stably placed on the first bottom plate 31a. On one side of each of the second bottom plate 41a, the second upper plate 41b, and the intermediate plate 41c, a cutout 42 into which one of the plurality of fixed struts 3 is inserted is provided. That is, the sub boat 217b includes the plurality of movable struts 4 provided with the second supports 22, respectively, and the second coupler 41 that fixes the plurality of movable struts 4 to each other. The sub boat 217b is provided to be movable in the vertical direction within a range in which an upper end and a lower end are restricted with respect to the main boat 217a. That is, as illustrated in an enlarged manner in FIG. 4, when the sub boat 217b is located on a lower side, an upper surface of the second support 22a is located below an upper surface of the first support 21a by a distance c1. In contrast, in consideration of a thickness (c3) of the wafer 200, the upper surface of the second support 22a is restricted so as to be located below a position (distance: c1+c2−c3) of a lower surface of the second support 22b so as not to abut a lower surface of the second support 22b when the sub boat 217b is located on an upper side.

Here, in the second bottom plate 41a, in a case where the number of the plurality of movable struts 4 is N (N is an integer not smaller than 3), the number of the plurality of fixed struts 3 is N−1 or N+1; at that time, the second bottom plate 41a is formed of a plate having at least N vertices, and the plurality of movable struts 4 is connected corresponding to the N vertices. The first support 21 of the fixed strut 3 is arranged so as to be closer to the center of the substrate 200 than the second support 22.

The driver 268 is configured to be able to lift the second support 22 relatively upward to float the substrate 200 from at least one first support 21. Specifically, in a configuration in which the main boat 217a and the sub boat 217b are combined, the sub boat 217b is configured to be movable in the vertical direction within a range in which the upper end and the lower end are restricted with respect to the main boat 217a. Then, in the middle of the film-forming processing, the driver 268 moves the sub boat 217b upward within a range in which the upper end and the lower end are restricted with respect to the main boat 217a, and simultaneously lifts the plurality of wafers 200.

When a thick film is formed on the substrate, the film is also formed on the substrate support (boat) itself depending on the film thickness, so that sticking between the substrate support and the substrate occurs, and particles are generated due to this. In order to reduce such particle generation, a method is conceivable in which, when a film having a certain thickness is formed, the substrate support is taken out from the processing furnace once, the substrate is lifted one by one by a transfer machine in a transfer chamber and returned to its original position, and the substrate support is loaded again in the processing furnace to form a thick film on the substrate. However, in this method, a film formation time may increase, a film quality may decrease due to oxidation, and a thermal history may become non-uniform. In contrast, as in the present embodiments, by lifting the substrate 200 in the processing container 201, the film formation time can be shortened and the film quality can be improved. Since an operation of simultaneously lifting the plurality of wafers 200 is performed under a reduced pressure in the processing furnace 202 (processing container 201), a throughput is dramatically improved. Since the substrate support is not moved to the transfer chamber, oxidation in the transfer chamber is suppressed, and the thermal history of the wafer 200 associated with tweezer pickup is reduced. This improves the film quality. Note that, in the transfer chamber, there is an atmosphere or a nitrogen (N₂) atmosphere with oxygen (O₂) of 20 ppm or less. Since a back surface (rear surface) of the substrate 200 is exposed in the processing container 201, the film is formed on both surfaces of a front surface and the back surface (rear surface) opposed to the front surface of the substrate 200, so that warpage of the substrate 200 can be prevented.

A temperature sensor 263 serving as a temperature detector is disposed in the reaction tube 203. By regulating a degree of energization to the heater 207 on the basis of temperature information detected by the temperature sensor 263, a desired temperature distribution can be achieved in the process chamber 201. The temperature sensor 263 is provided along the inner wall of the reaction tube 203.

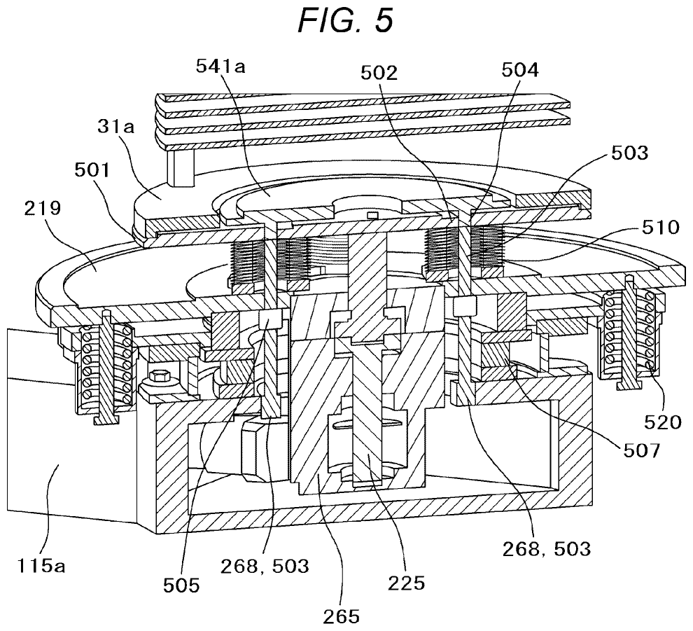

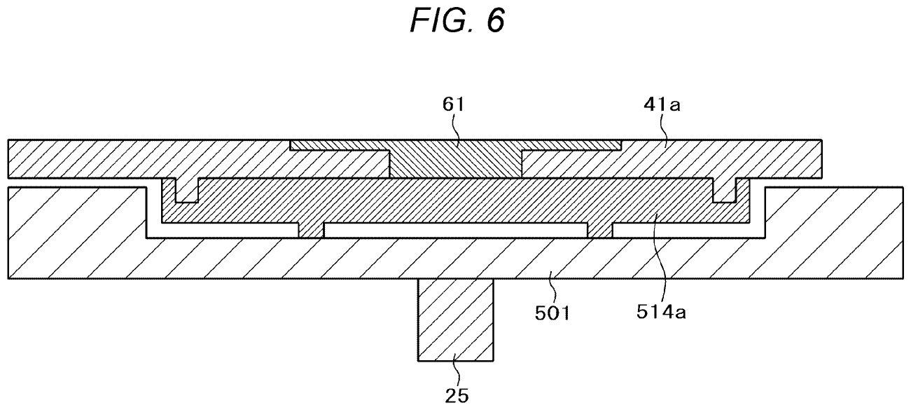

Next, the configuration of the driver 268 and a sub boat loading table will be described with reference to FIGS. 5 and 6. FIG. 5 is a cross-sectional perspective view for illustrating the driver suitably used in an aspect of the present disclosure. FIG. 6 is a cross-sectional view for illustrating the sub boat loading table to which the sub boat 217b suitably used in an aspect of the present disclosure is fixed.

FIG. 5 is a cross-sectional perspective view between an elevator arm 115a of the boat elevator 115, and a boat table 501 on which the first bottom plate 31a is loaded and a sub boat loading table 541a on which the second bottom plate 41a is loaded. The rotator 267 including the rotation shaft 255 is provided on the elevator arm 115a, and the rotation shaft 225 penetrates the seal cap 219 and is connected to the boat table 501. The rotation shaft 225 rotatably supports the boat table 501. A disk-shaped boat table 501, with the rotation shaft 225 fixed, supports the main boat 217a and the sub boat 217b thereon. The boat table 501 is composed of, for example, a metal material such as SUS into a disk shape. On the boat table 501, the sub boat loading table 541a to which a disk-shaped second bottom plate 41a is fixed is loaded, and a ring-shaped first bottom plate 31a is loaded around the loading table 541a. The boat table 501 includes a plurality of openings 502 provided at positions corresponding to a plurality of pins 503 to be described later, and a plurality of pushers (hanging pins) 504 vertically movably hung so as to be supported in the plurality of openings 502, respectively.

The plurality of pins 503 corresponds to the driver 268 in this example. A guide (joint) 505 is provided below the seal cap 219 on the plurality of pins 503. The plurality of pins 503 is provided to penetrate the seal cap 219 while maintaining airtightness of the seal cap 219 by a first bellows 510 provided between the boat table 501 and the seal cap 219. The sub boat loading table 541a is configured to be pushed upward by the pushers 504 pushed up by the plurality of pins 503. That is, one end of each of the plurality of pins 503 outside the processing container 201 is in contact with or fixed to the elevator arm 115a. The other end of each of the plurality of pins 503 inside the processing container 201 is configured to be able to push the sub boat loading table 541a to which the second bottom plate 41a is fixed upward. According to this, the plurality of movable struts 4 is configured to be lifted at once.

A space between the rotator 267 and the seal cap 219 fixed to the elevator arm 115a is sealed with a second bellows 507 provided so as to surround the rotation shaft 225.

A plurality of elastic supports 520 is provided between the elevator arm 115a and the seal cap 219 to energize the seal cap 219 upward. The plurality of elastic supports 520 is provided around the second bellows 507. The plurality of elastic supports 520 is composed of, for example, a spring and a pin that applies a force upward by the spring. When the elastic support 520 is compressed by a predetermined amount or more, the plurality of pins 503 of the driver 268 bulges upward relative to the seal cap 219, and pushes upward one or more of the plurality of movable struts 4 connected to the sub boat loading table 541a.

The driver 268 (the plurality of pins 503) illustrated in FIG. 5 has an effect that a new driver is not needed.

FIG. 6 illustrates the sub boat loading table 541a to which the second bottom plate 41a of the sub boat 217b is fixed. The sub boat loading table 541a is disposed on the boat table 501 to which the rotation shaft 225 is fixed. The second bottom plate 41a of the sub boat 217b is disposed on the sub boat loading table 541a and is screwed to a member 61 made of metal. As a result, the sub boat 217b is fixed to the sub boat loading table 541a. The sub boat 217b fixed to the sub boat loading table 541a is elevated by lifting the sub boat loading table 541a, and the wafer 200 can be lifted from the main boat 217a in the reaction chamber 201.

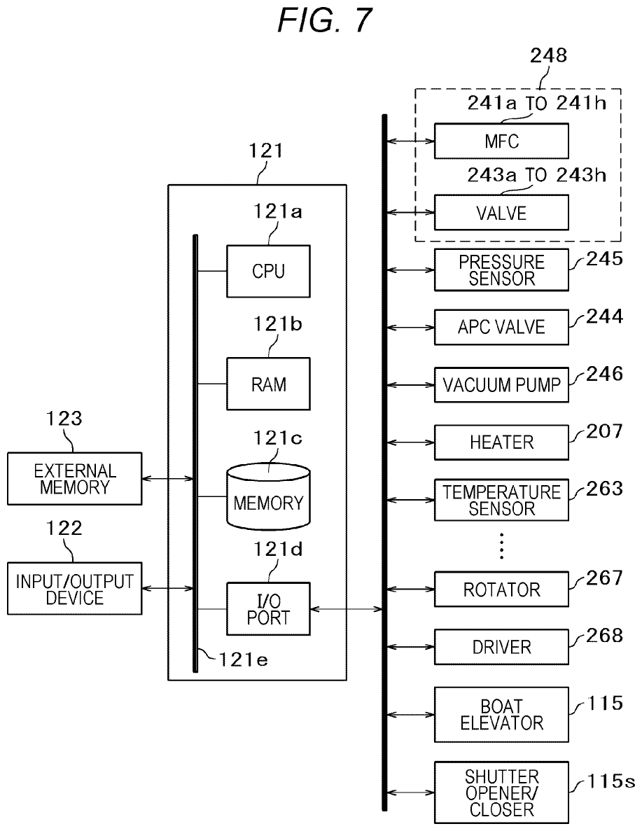

As illustrated in FIG. 7, a controller 121, which is a controller (controller, controller) is formed as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus 121e. An input/output device 122 configured as, for example, a touch panel and the like is connected to the controller 121. An external memory 123 can be connected to the controller 121.

The memory 121c includes, for example, a flash memory, a hard disk drive (HDD), a solid state drive (SSD) and the like. A control program for controlling an operation of the substrate processing apparatus, a process recipe in which procedures, conditions and the like of substrate processing to be described later are described and the like are readably stored in the memory 121c. The process recipe is a combination that allows the controller 121 to allow the substrate processing apparatus to execute each procedure in the substrate processing to be described later to obtain a predetermined result, and serves as a program. Hereinafter, the process recipe, the control program and the like are collectively and simply referred to as a program. The process recipe is simply referred to as a recipe. In a case where a term “program” is used in this specification, this might include a case where a single recipe alone is included, a case where a single control program alone is included, or a case where both of them are included. The RAM 121b is configured as a memory area (work area) in which programs, data and the like read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opener/closer 115s and the like described above.

The CPU 121a is configured to be able to read the control program from the memory 121c and execute the same, and read the recipe from the memory 121c in response to an input and the like of an operation command from the input/output device 122. The CPU 121a is configured to be able to control, in accordance with a content of the read recipe, a flow rate regulating operation of various substances (various gases) by the MFCs 241a to 241h, an opening/closing operation of the valves 243a to 243h, a pressure regulating operation by the APC valve 244 on the basis of an opening/closing operation of the APC valve 244 and the pressure sensor 245, start and stop of the vacuum pump 246, a temperature regulating operation of the heater 207 on the basis of the temperature sensor 263, rotation and rotation speed adjusting operation of the boat 217 by the rotator 267, a vertical operation of the sub boat 217b by the driver 268, an elevating operation of the boat 217 by the boat elevator 115, an opening/closing operation of the shutter 219s by the shutter opener/closer 115s and the like.

The controller 121 can be composed by installation of the above-described program stored in the external memory 123 into the computer. Examples of the external memory 123 include a magnetic disk such as an HDD, an optical disk such as a CD, a magneto-optical disk such as an MO, and a semiconductor memory such as a USB memory or an SSD, for example. The memory 121c and the external memory 123 are configured as computer-readable recording media. Hereinafter, they are collectively and simply referred to as recording media. In a case where the term “recording medium” is used in this specification, this might include the memory 121c alone, the external memory 123 alone, or both of them. Note that the program may be provided to the computer by using a communicator such as the Internet or a dedicated line without using the external memory 123.

The controller 121 controls to perform a step a of supplying a gas from a gas supplier (232d, 241d, 243d, 232a, nozzle 249a) while rotating the boats (217a, 217b) to process the substrate 200 supported by the boats (217a, 217b), and a step b of sequentially or simultaneously separating the substrate 200 from the first support 21a while maintaining the substrate 200 in the processing container 201 a predetermined number of times, and to form a film having a predetermined film thickness or more on the substrate 200.

### (2) Substrate Processing Step

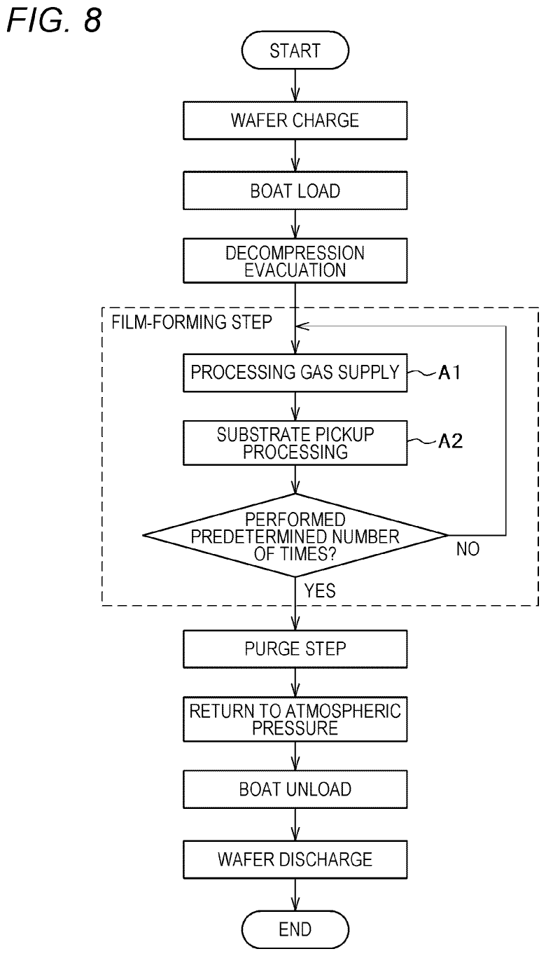

Using the substrate processing apparatus described above, an example of a method of processing the substrate, that is, a processing sequence of allowing a film to grow on the surface of the wafer 200 serving as the substrate will be described as a step of a method of manufacturing a semiconductor device with reference to FIG. 8. In the following description, an operation of each unit included in the substrate processing apparatus is controlled by the controller 121.

The term “wafer” used in this specification might mean the wafer itself, or a stack of the wafer and a predetermined layer or film formed on a surface thereof. The term “surface of the wafer” used in this specification might mean the surface of the wafer itself or a surface of a predetermined layer and the like formed on the wafer. The expression “forming a predetermined layer on the wafer” in this specification might mean that a predetermined layer is directly formed on the surface of the wafer itself or that a predetermined layer is formed on the layer and the like formed on the wafer. In a case where the term “substrate” is used in this specification, this is a synonym of the term “wafer”.

### (Wafer Charge and Boat Load)

When a plurality of wafers 200 is loaded on the boat 217 (wafer charge), the shutter opener/closer 115s moves the shutter 219s, and the lower end opening of the manifold 209 is opened (shutter open). Thereafter, as illustrated in FIG. 1, the boat 217 that supports the plurality of wafers 200 is lifted by the boat elevator 115 and is loaded into the process chamber 201 (boat load). In this state, the seal cap 219 seals the lower end of the manifold 209 via the O-ring 220b. In this manner, the wafer 200 is loaded into the process chamber 201.

### (Pressure Regulation and Temperature Regulation)

After the boat load is finished, the inside of the process chamber 201, that is, a space in which the wafer 200 is present is vacuum-exhausted (decompression-exhausted) by the vacuum pump 246 so as to achieve a desired pressure (vacuum degree). At that time, the pressure in the process chamber 201 is measured by the pressure sensor 245, and the APC valve 244 is feedback-controlled on the basis of information of the measured pressure. The heater 207 heats such that that temperature of the wafer 200 in the process chamber 201 reaches desired processing temperature (first temperature). In this case, on the basis of the temperature information detected by the temperature sensor 263, a degree of energization to the heater 207 is feedback-controlled such that that a desired temperature distribution is obtained in the process chamber 201. The rotator 267 starts rotating the wafer 200. The exhaust in the process chamber 201, the heating and rotation of the wafer 200 continue at least until the processing on the wafer 200 is finished.

### [Film-Forming Step (A1, A2)]

### (Step A1: Reactant Gas Supplying Step]

At step A1, in a state in which the wafer 200 is heated to predetermined temperature, at least one of the first processing gas and the second processing gas is supplied to the wafer 200 to perform the film-forming processing of allowing the film to grow on the surface of the wafer 200.

In a case of depositing a SiGe film, the second processing gas is flown into the gas supply pipe 232c. The second processing gas, a flow rate of which is regulated by the MFC 241c, is supplied into the process chamber 201 via the gas supply pipe 232c and the nozzle 249c. In this state, the valve 243d is opened and the first processing gas is flown in the gas supply pipe 232d. The first processing gas, a flow rate of which is regulated by the MFC 241d, is supplied into the process chamber 201 via the gas supply pipe 232a and the nozzle 249a, and discharged from the exhaust port 231a together with the second processing gas. At that time, the first processing gas and the second processing gas are supplied to the wafer 200 from a lateral side of the wafer 200. At that time, the valves 243f to 243h may be opened to supply the inert gas into the process chamber 201 via the nozzles 249a to 249c, respectively.

Processing conditions at step A1 are exemplified as follows:
processing temperature (predetermined temperature): 500 to 650° C., preferably 550 to 600° C.,
processing pressure: 4 to 200 Pa, preferably 1 to 120 Pa,
first processing gas supply flow rate: 0.1 to 5 slm, preferably 0.2 to 3 slm,
second processing gas supply flow rate: 0.1 to 5 slm, preferably 0.2 to 310 slm,
inert gas supply flow rate (for each gas supply pipe): 0 to 20 slm, preferably, 0.1 to 10 slm, and
gas supply time: 20 minutes to 60 hours, preferably 30 to 360 minutes.

By supplying the first processing gas and the second processing gas to the wafer 200 under the above-described processing conditions, an epitaxial SiGe film serving as a specific element-containing film, for example, can be formed as an epitaxial film on the surface of the wafer 200. Note that the Si film can be formed by supplying the first processing gas alone as the source gas.

After step A1 is finished, the valves 243a and 243c are closed, and the supply of the first processing gas and the second processing gas into the process chamber 201 is stopped.

### (Step A2: Substrate Pickup Processing)

After step A1, the sub boat 217b is moved relatively upward by the driver 268, and the plurality of wafers 200 is simultaneously lifted from the main boat 217a. After a certain time elapses, the sub boat 217b is moved relatively downward by the driver 268, and the plurality of wafers 200 is simultaneously arranged on the main boat 217a.

### [Predetermined Number of Times of Execution]

A cycle in which steps A1 and A2 described above are alternately performed is performed a predetermined number of times (n times, n is an integer not smaller than 1).

### (Purge Step)

After the film-forming step is finished, the inert gas serving as the purge gas is supplied from each of the nozzles 249a to 249c into the process chamber 201 and is discharged from the exhaust port 231a. As a result, the inside of the process chamber 201 is purged, and a gas, a by-product and the like remaining in the process chamber 201 are removed from the inside of the process chamber 201 (after-purge). Thereafter, the atmosphere in the process chamber 201 is replaced with the inert gas (inert gas replacement), so that the pressure in the process chamber 201 is restored to a normal pressure (atmospheric pressure restoration).

### (Boat Unload and Wafer Discharge)

After that, the boat elevator 115 lowers the seal cap 219, and the lower end of the manifold 209 is opened. Then, the processed wafer 200 is unloaded from the lower end of the manifold 209 to the outside of the reaction tube 203 in a state of being supported by the boat 217 (boat unload). After the boat unload, the shutter 219s is moved, and the lower end opening of the manifold 209 is sealed by the shutter 219s via the O-ring 220c (shutter close). After being unloaded to the outside of the reaction tube 203, the processed wafer 200 is taken out from the boat 217 (wafer discharge).

### MODIFIED EXAMPLE

Hereinafter, a modified example of a driver 268 will be described.

### Modified Example 1

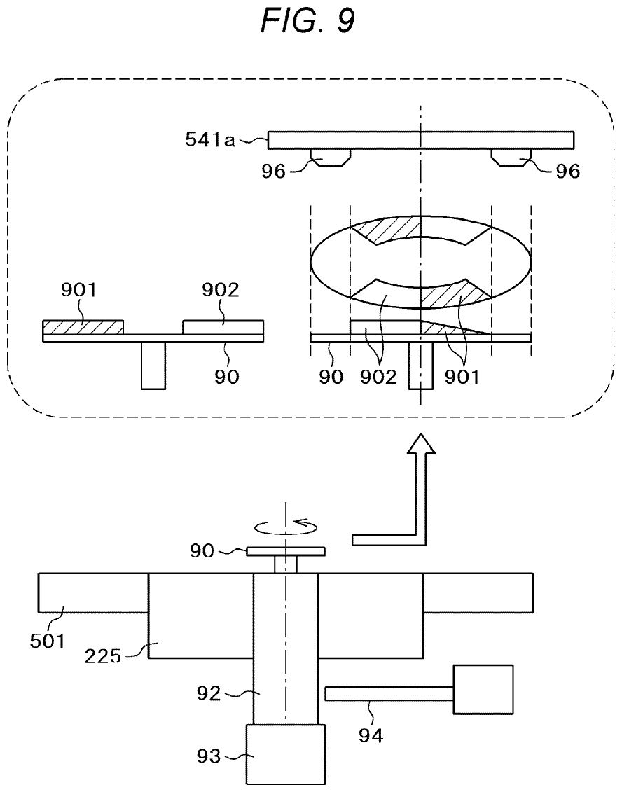

FIG. 9 is a diagram for illustrating a driver according to Modified Example 1.

A driver 268 includes an inner shaft 92 that is arranged inside a cylindrical rotation shaft 225 to which a boat table 501 is fixed and is rotatable relative to the rotation shaft 225, a motor 93 that rotates the inner shaft 92, a rotation plate 90 that is fixed to the inner shaft 92 such that that an upper surface thereof and a rear surface of a second bottom plate 41a face each other, and a lock 94 that fixes rotation of the inner shaft 92 with respect to the motor 93 or an elevator arm 115a and releases fixation.

When the inner shaft 92 is locked by the lock 94, the rotation shaft 225 alone rotates, and the rotation of the inner shaft 92 is fixed. In contrast, when the inner shaft 92 is unlocked by the lock 94, the fixation of the rotation of the inner shaft 92 is released, and the rotation shaft 225 and the inner shaft 92 rotate.

The upper surface of the rotation plate 90 is provided with a slope 901 a height of which continuously changes in a circumferential direction and a rectangular protrusion 902 continuous with the slope 901. The upper surface of the slope 901 and an upper surface of the rectangular protrusion 902 are configured to be continuous. In this example, the slope 901 and the rectangular protrusion 902 are also provided at point-symmetrical positions with respect to the center of the rotation plate 90.

The slope 901 of the rotation plate 90 is configured to be able to convert relative rotation into vertical movement. This relative rotation is achieved by a rotator 267 rotating the rotation shaft 225 in a state in which the inner shaft 92 is fixed by the lock 94.

In contrast, a follower 96 that slides with respect to the slope 901 is provided on the rear surface of the second bottom plate 41a. When the rotation plate 90 and the second bottom plate 41a relatively rotate, the follower 96 slides on the slope 901, and the second bottom plate 41a moves upward. As a result, it becomes possible to lift a wafer 200 from a main boat 217a in a reaction chamber 201 by elevating a sub boat 217b.

Note that the slope 901 can be provided on at least one of the second bottom plate 41a and the rotation plate 90, and the follower 96 can be provided on the other of the second bottom plate 41a and the rotation plate 90.

Here, in a case where a film-forming step (A1) of supplying gas from a gas supplier (232d, 241d, 243d, 232a, nozzle 249a) while rotating the boats (217a, 217b) to process a substrate 200 supported by the boats (217a, 217b) and a substrate pickup step (A2) of sequentially or simultaneously separating the substrate 200 from a first support 21a while maintaining the substrate 200 in the processing container 201 are performed, after the substrate pickup step (A2), the substrate 200 is returned to the same angle as a rotation angle at which the substrate 200 was placed before the substrate pickup step (A2). That is, the inner shaft 92 is relatively rotated with respect to the rotation shaft 225 in a state in which the inner shaft 92 is fixed by the lock 94; for example, in a case where the inner shaft 92 is relatively rotated by 90 degrees with respect to the rotation shaft 225 in the substrate pickup step (A2), the inner shaft 92 is relatively rotated by 270 degrees with respect to the rotation shaft 225 after the substrate pickup step (A2), and the substrate 200 is returned to the same angle as the rotation angle at which the substrate 200 was placed before the substrate pickup step (A2). As a result, a region of the substrate 200 in contact with the boats (217a, 217b) is fixed, and expansion of particles, contamination, and defects can be suppressed. Even if the substrate pickup step (A2) is performed a plurality of times, angle deviation is less likely to accumulate, so that it is possible to eliminate the need for additional notch alignment when the processed substrate 200 is accommodated in a substrate container.

### Modified Example 2

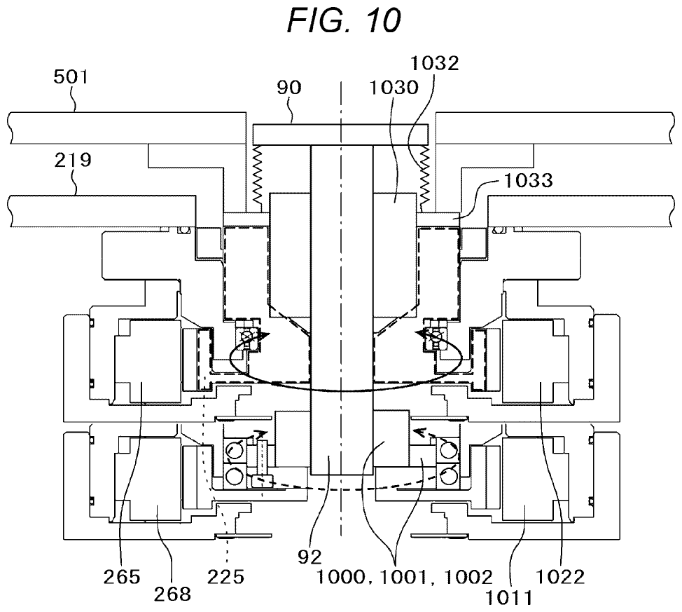

FIG. 10 is a diagram for illustrating a driver according to Modified Example 2. In a driver 268 of Modified Example 2, an inner shaft 92 capable of vertically moving with respect to a rotation shaft 225 is provided inside a cylindrical rotation shaft 225 to which a boat table 501 is fixed, and a motor 1011 that rotates and vertically moves the inner shaft 92 is provided. In contrast, a rotator 265 is provided with a main motor 1022 that rotates the rotation shaft 225.

A feed screw mechanism 1000 is provided on the inner shaft 92. The feed screw mechanism 1000 includes a male screw 1001 and a female screw 1002, one of the male screw 1001 and the female screw 1002 is fixed to the inner shaft 92, and the other of the male screw 1001 and the female screw 1002 is rotated by the motor 1011. As a result, a rotation plate 90 fixed to inner shaft 92 can be pushed up, so that a second bottom plate 41a can be pushed up. A million guide 1030 is provided between the rotation shaft 225 and the inner shaft 92 in the middle of the inner shaft 92. A bellows 1032 that maintains airtightness of the inner shaft 92 is provided on a component 1033 provided between the boat table 501 and the rotation shaft 225 and a lower surface of the rotation plate 90.

The main motor 1022 included in the rotator 265 is directly connected to the rotation shaft 225 without using a transmission. The motor 1011 included in the driver 268 is directly connected to the other of the male screw 1001 and the female screw 1002 without using a transmission. Axes of rotation of the main motor 1022 and the motor 1011 are arranged coaxially.

Since the rotation and pushing up of the inner shaft 92 are 1011, there are effects that controlled by the motor controllability is excellent and positioning accuracy is also excellent. There also is an effect of low particle.

### Modified Example 3

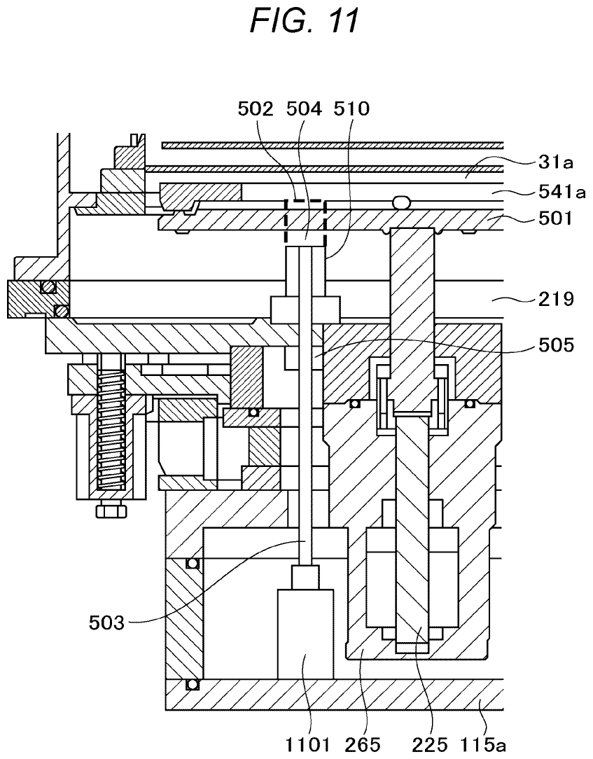

FIG. 11 is a diagram for illustrating a driver according to Modified Example 3. Modified Example 3 has a configuration in which each of a plurality of pins 503 described with reference to FIG. 5 is provided so as to be vertically movable by an actuator 1101 such as an air cylinder. Other configurations of FIG. 11 are the same as the configurations of FIGS. 5 and 6, and redundant description will be omitted.

That is, a driver 268 is configured to include a plurality of pins 503 provided so as to penetrate a seal cap 219 to be vertically movable while maintaining airtightness of the seal cap 219 by a bellows 510, and a plurality of actuators 1101 provided on a one-to-one basis with the plurality of pins 503 and driven synchronously. The actuator 1101 is in contact with or fixed to an upper side of an elevator arm 115a.

Although the present disclosure is specifically described above on the basis of the examples, the present disclosure is not limited to the above embodiments and examples, and it goes without saying that various modifications can be made.

The present disclosure can provide a technique for preventing sticking of a substrate to a support accompanying film formation.

What is claimed is:

1. A substrate processing apparatus comprising:
a boat including at least one first support for one substrate;
a processing container configured to accommodate the boat and process the substrate that is placed therein;
a gas supplier configured to supply a processing gas into the processing container;
a plurality of second supports provided so as to be relatively movable in a vertical direction with respect to the boat;
a rotator including a rotation shaft that rotatably supports the boat;
a driver configured to be capable of lifting the second supports relatively upward to float the substrate from the at least one first support; and
a controller configured to be capable of controlling to form a film on the substrate by performing: (a) supplying a gas from the gas supplier while rotating the boat to process the substrate supported by the boat, and (b) separating the substrate from the first support while maintaining the substrate in the processing container a predetermined number of times.

2. The substrate processing apparatus according to claim 1, further comprising:
a sub boat including a plurality of movable struts provided with the second supports, respectively, and a second coupler that fixes the plurality of movable struts to each other, the sub boat provided so as to be movable in a vertical direction within a range in which an upper end and a lower end are restricted with respect to the boat.

3. The substrate processing apparatus according to claim 2, wherein:
the boat includes a plurality of fixed struts extending in a direction substantially perpendicular to the substrate and provided with the first support, and a first coupler that fixes the plurality of fixed struts to each other,
the first coupler includes a first bottom plate that fixes vicinities of lower ends of the plurality of fixed struts to each other, and
the second coupler includes a second bottom plate that fixes vicinities of lower ends of the plurality of movable struts to each other and has a shape capable of being stably placed on the first bottom plate.

4. The substrate processing apparatus according to claim 3, wherein:
the number of the plurality of movable struts is N (N is an integer not smaller than 3), the number of the plurality of fixed struts is N−1 or N+1, the second bottom plate is a plate having at least N vertices, and the plurality of movable struts is connected corresponding to the N vertices.

5. The substrate processing apparatus according to claim 4, further comprising:
a cutout provided on one side of the second bottom plate and into which the plurality of fixed struts is inserted.

6. The substrate processing apparatus according to claim 2, wherein:
the movable struts are arranged so as to be rotatable together with the boat on an outer periphery of the substrate supported by the boat in a manner capable of being separated from and in contact with the driver.

7. The substrate processing apparatus according to claim 1, wherein:
the first support is arranged at a position closer to the center of the substrate than the second supports.

8. The substrate processing apparatus according to claim 3, further comprising:
a lid that is provided at a lower end of the processing container and closes an opening through which the substrate can be taken in and out;
an elevator arm configured to vertically drive the rotator and the lid; and
an elastic support that is provided between the elevator arm and the lid and energizes the lid upward, wherein:
the driver includes a plurality of pins that bulges upward relative to the lid and pushes upward at least one or more of the plurality of movable struts when the elastic support is compressed by a predetermined amount or more.

9. The substrate processing apparatus according to claim 8, wherein:
the plurality of pins is provided to penetrate the lid while maintaining airtightness of the lid by a bellows, each one end outside the processing container is in contact with or fixed to the elevator arm, the other end inside the processing container is configured to be able to push the second bottom plate upward, and the plurality of movable struts is collectively lifted.

10. The substrate processing apparatus according to claim 9, wherein:
the rotator is fixed to the elevator arm, and a space between the rotator and the lid is sealed by a second bellows provided so as to surround the rotation shaft.

11. The substrate processing apparatus according to claim 9, further comprising:
a disk-shaped boat table on which the rotation shaft is fixed and on which the boat is supported, wherein:
the boat table includes a plurality of openings provided at positions corresponding to the plurality of pins, and pushers vertically movably hung so as to be supported in the plurality of openings, respectively, and
the second bottom plate is pushed upward by the pushers pushed up by the plurality of pins.

12. The substrate processing apparatus according to claim 3,
wherein: the driver includes an inner shaft that is arranged inside a cylindrical rotation shaft and is rotatable relative to the rotation shaft, a motor that rotates the inner shaft, and a rotation plate that is fixed to the inner shaft so as to face the second bottom plate, and
at least one of the second bottom plate and the rotation plate is provided with a slope a height of which continuously changes in a circumferential direction, and is configured to be capable of converting the relative rotation into vertical movement.

13. The substrate processing apparatus according to claim 12, wherein:
a follower that slides with respect to the slope is provided on the other of the second bottom plate and the rotation plate.

14. The substrate processing apparatus according to claim 12, further comprising:
a lock configured to fix rotation of the inner shaft with respect to the motor and release the fixation, wherein:
the relative rotation is achieved by the rotator rotating the rotation shaft in a state in which the inner shaft is fixed.

15. The substrate processing s according to claim 1, wherein:
after the (b), the substrate is returned to the same angle as a rotation angle at which the substrate was placed before the (b).

16. The substrate processing apparatus according to claim 3, wherein:
the driver includes an inner shaft that is arranged inside a cylindrical rotation shaft and is vertically movable with respect to the rotation shaft, a feed screw mechanism in which one of a male screw and a female screw is fixed to the inner shaft, and a motor that rotates the other of the male screw and the female screw, and
the inner shaft is configured to be capable of pushing up the first coupler.

17. The substrate processing apparatus according to claim 16, wherein:
a main motor included in the rotator and the motor included in the driver are coaxially arranged, and are directly connected to the rotation shaft and the other of the male screw and the female screw without using a transmission.

18. The substrate processing apparatus according to claim 1, further comprising:
a lid that is provided at a lower end of the processing container and closes an opening through which the substrate can be taken in and out, wherein:
the driver includes a plurality of pins provided so as to penetrate the lid to be vertically movable while maintaining airtightness of the lid by a bellows, and a plurality of actuators provided on a one-to-one basis with the plurality of pins and driven synchronously.

19. A method of manufacturing a semiconductor device, comprising:
forming a film on a substrate by performing:
(a) accommodating a boat on which the substrate is placed in a processing container r of a substrate processing apparatus provided with the boat including at least one first support for one substrate, the processing container that accommodates the boat and processes the substrate that is placed, a gas supplier that supplies a processing gas into the processing container, a plurality of second supports provided so as to be relatively movable in a vertical direction with respect to the boat, a rotator including a rotation shaft that rotatably supports the boat, and a driver that is capable of lifting the second supports relatively upward to float the substrate from the at least one first support, and supplying a gas from the gas supplier while rotating the boat to process the substrate supported by the boat, and
(b) separating the substrate from the first support while maintaining the substrate in the processing container a predetermined number of times.

20. A non-transitory computer-readable recording medium storing a program that causes, by a computer, a substrate processing apparatus to perform:
forming a film on a substrate by performing:
a procedure A of accommodating a boat on which the substrate is placed in a processing container of a substrate processing apparatus provided with the boat including at least one first support for one substrate, the processing container that accommodates the boat and processes the substrate that is placed, a gas supplier that supplies a processing gas into the processing container, a plurality of second supports provided so as to be relatively movable in a vertical direction with respect to the boat, a rotator including a rotation shaft that rotatably supports the boat, and a driver that is capable of lifting the second supports relatively upward to float the substrate from the at least one first support, and supplying a gas from the gas supplier while rotating the boat to process the substrate supported by the boat, and
a procedure B of separating the substrate from the first support while maintaining the substrate in the processing container a predetermined number of times.
